(19) United States
(12) Patent Application Publication
(10) Pub. No.: US 2021/0288011 A1
(43) Pub. Date: Sep. 16, 2021

(54) INTEGRATED CIRCUIT COMPRISING AN INTERCONNECTION PART INCLUDING A PROTRUDING SOLDER ELEMENT AND CORRESPONDING PRODUCTION METHOD

(71) Applicant: STMicroelectronics (Grenoble 2) SAS, Grenoble (FR)

(72) Inventor: Caroline MOUTIN, Sassenage (FR)

(73) Assignee: STMicroelectronics (Grenoble 2) SAS, Grenoble (FR)

(21) Appl. No.: 17/195,975

(22) Filed: Mar. 9, 2021

(30) Foreign Application Priority Data
Mar. 12, 2020 (FR) 2002456

(51) Int. Cl. H01L 23/00; H01L 23/532; H01L 23/528; H01L 21/768

(52) U.S. Cl. CPC H01L 24/14; H01L 23/53228; H01L 23/53214; H01L 21/76838; H01L 24/11; H01L 21/76802; H01L 23/528

(57) ABSTRACT

An integrated circuit includes an interconnection part formed by a last metal level and at least one protruding solder element disposed on a connection site. The connection site includes a first aluminum sheet connected with the last metal level and at least a second aluminum sheet disposed on the first aluminum sheet and under the protruding solder element.

### PRIORITY CLAIM

This application claims the priority benefit of French Application for Patent No. 2002456, filed on Mar. 12, 2020, the content of which is hereby incorporated by reference in its entirety to the maximum extent allowable by law.

### TECHNICAL FIELD

Embodiments and implementations relate to integrated circuits and, in particular, to solder elements of interconnection parts of integrated circuits.

### BACKGROUND

Conventionally, a solder element is a metallic connection element of an integrated circuit, such as a ball, a contact, or a pillar, formed on the top of an interconnection part, referred to as a “BEOL” (acronym of the standard term “Back End Of Line”) part. The solder element is electrically connected to the interconnection part of the integrated circuit.

The “BEOL” interconnection part typically includes metal levels particularly forming a grid of electrical couplings between electronic elements of a semiconductor chip and external elements.

In the conventional orientation of interconnection parts, the first metal level is the level closest to the semiconductor chip, whereas the last metal level is the level at the greatest distance from the semiconductor chip.

When mounting the integrated circuit on a third-party device, the solder elements of the integrated circuit are disposed facing respective connection elements of the third-party device.

The solder elements are then linked to the connection elements of the third-party device. This link is conventionally produced by a partial fusing of the solder elements of the integrated circuit, thanks to a local or generalized heat treatment. The link electrically connects, and mechanically links, the integrated circuit and the third-party device.

Conventional solder elements have difficulties insofar as delaminations can appear following the assembly between the integrated circuit and the third-party device. Typically, a delamination can occur under the solder element between different levels of the “BEOL” interconnection part, for example during a heat treatment. Delaminations can, for example, occur at the level of inter-metal dielectric layers of the “BEOL” interconnection part. Delaminations can cause the rupture of the electrical and mechanical link between the integrated circuit and the third-party device.

The delamination phenomenon is more likely, and therefore more problematic, when the dielectric materials of the interconnection part has a “low-k” or “ultra-low-k” dielectric constant (according to standard terminology).

Thus, it is desirable to limit this delamination phenomenon to prevent it from causing an electrical and/or mechanical rupture between the solder element and the interconnection part of the integrated circuit.

### SUMMARY

According to an aspect, an integrated circuit comprises an interconnection part including a last metal level and at least one protruding solder element disposed on a connection site, wherein the connection site includes a first aluminum sheet connected with the last metal level, and at least a second aluminum sheet disposed on the first aluminum sheet and under the protruding solder element.

Thus, the presence of the first aluminum sheet and the second aluminum sheet makes it possible to increase the mechanical stress absorption capacity of the connection site. Thus, the interconnection part is protected from this stress and this makes it possible to reduce the risk of delamination in the interconnection part.

Indeed, it was observed that the presence of two aluminum sheets in the connection site, between the protruding solder element and the interconnection part of the last metal level, enhances the delamination resistance of the metal levels and the inter-metal dielectrics, in particular the last levels, of the interconnection part.

According to an embodiment, the connection site comprises an intermediate bonding layer including tantalum and/or tantalum nitride, located between the first aluminum sheet and the second aluminum sheet.

For example, the intermediate bonding layer comprises a stack of at least one layer of tantalum and at least one layer of tantalum nitride.

Thus, the intermediate bonding layer made of tantalum and/or tantalum nitride promotes the bonding of the second aluminum sheet with the first aluminum sheet and makes it possible to increase the aluminum thickness in the connection site. This makes it possible to absorb mechanical stress and enhances the resistance of the interconnection part to stress causing delaminations.

According to an embodiment, the protruding solder element is a copper pillar and the interconnection part includes several metal levels separated by inter-metal dielectric layers, at least some of the inter-metal dielectric layers including a material having a low dielectric constant. For example, the low dielectric constant material (usually referred to as “low-k”) has a dielectric constant less than the dielectric constant of silicon dioxide, for example between 2 and 3.

A copper pillar by way of solder element has advantages in terms of size and cost. Nevertheless, in conventional technologies, due to the rigidity of copper, the copper pillar absorbs little mechanical stress particularly during assembly, and tends to transmit stress into the interconnection part, inducing delaminations.

Low dielectric constant dielectric materials are advantageous for reducing the size of integrated circuits, but display in conventional technologies a high delamination risk.

However, in the electronic circuit according to this aspect, the first and second aluminum sheets make it possible to absorb mechanical stress and particularly the mechanical stress that the copper pillar transmits, in the interconnection part.

Thus, this embodiment envisages both a copper pillar and low dielectric constant dielectric materials while benefiting from a significantly reduced delamination risk.

According to an embodiment, the first aluminum sheet is partially coated with a dielectric layer comprising an opening facing the first aluminum sheet, and the second aluminum sheet rests on the first aluminum sheet in the opening, and on the parts of the dielectric layer covering the first aluminum sheet.

According to a further aspect, a method for producing an integrated circuit is proposed, comprising: forming an interconnection part including a last metal level; forming a connection site comprising forming a first aluminum sheet connected to the last metal level of the interconnection part and forming a second aluminum sheet on the first aluminum sheet; and forming at least one protruding solder element on the connection site and above the second aluminum sheet.

According to an implementation, forming the connection site further comprises: forming an intermediate bonding layer including tantalum and/or tantalum nitride, located between the first aluminum sheet and the second aluminum sheet.

According to an implementation, forming the intermediate bonding layer comprises forming a stack made of at least one layer of tantalum and at least one layer of tantalum nitride.

According to an implementation, forming the protruding solder element comprises forming a copper pillar, and forming the interconnection part comprises forming metal levels and inter-metal dielectric layers separating the metal levels, at least some of the inter-metal dielectric layers being formed with a material having a low dielectric constant.

According to an implementation, forming the connection site further comprises: forming a dielectric layer so as to cover the first aluminum sheet; and forming an opening in the dielectric layer facing the first aluminum sheet; wherein the second aluminum sheet is formed so as to rest on the first aluminum sheet in the opening, and on parts of the dielectric layer covering the first aluminum sheet.

According to an implementation, the first aluminum sheet and the second aluminum sheet are formed by a vapor phase deposition and by an etching.

According to an implementation, the intermediate bonding layer is formed by a vapor phase deposition and by an etching.

### BRIEF DESCRIPTION OF THE DRAWINGS

Further advantages and features of the invention will emerge on studying the detailed description of embodiments and implementations, in no way restrictive, and of the appended drawing wherein:

FIG. 1 illustrates a sectional view of a “Back End Of Line” interconnection part of an integrated circuit, and

FIG. 2 is flow diagram.

### DETAILED DESCRIPTION

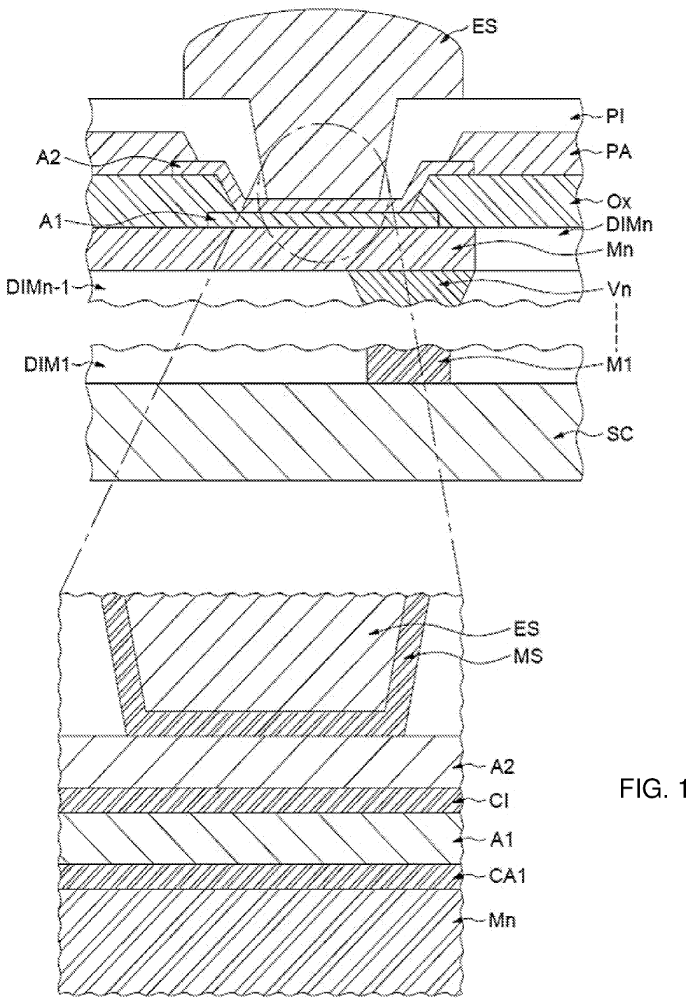

FIG. 1 illustrates a sectional view of a “BEOL” (acronym of the standard term “Back End Of Line”) interconnection part of an integrated circuit, including protruding solder elements ES forming an external physical interface of the integrated circuit. FIG. 1 also illustrates an enlargement of a central zone of this sectional view.

The interconnection part comprises an overlay of metal levels and inter-metal dielectric layers, disposed on a semiconductor substrate SC comprising functional components of the integrated circuit.

Hereinafter in the present description, the semiconductor substrate SC is defined as the “bottom” of the integrated circuit, as opposed to the “top” of the integrated circuit comprising the interconnection part.

The semiconductor substrate SC is covered with a first metal level M1 of the interconnection part of the integrated circuit. A last metal level Mn of the interconnection part is located above the first metal level M1. The last metal levels are electrically connected to one another by metallic vias Vn traversing the inter-metal dielectric layers DIM1, DIMn−1, DIMn. It is understood that they can be any number of metal levels and corresponding inter-metal dielectric layers between the first metal level M1 and the last metal level Mn.

The first metal level M1 and the last metal level Mn can be conventionally produced from copper or a copper alloy.

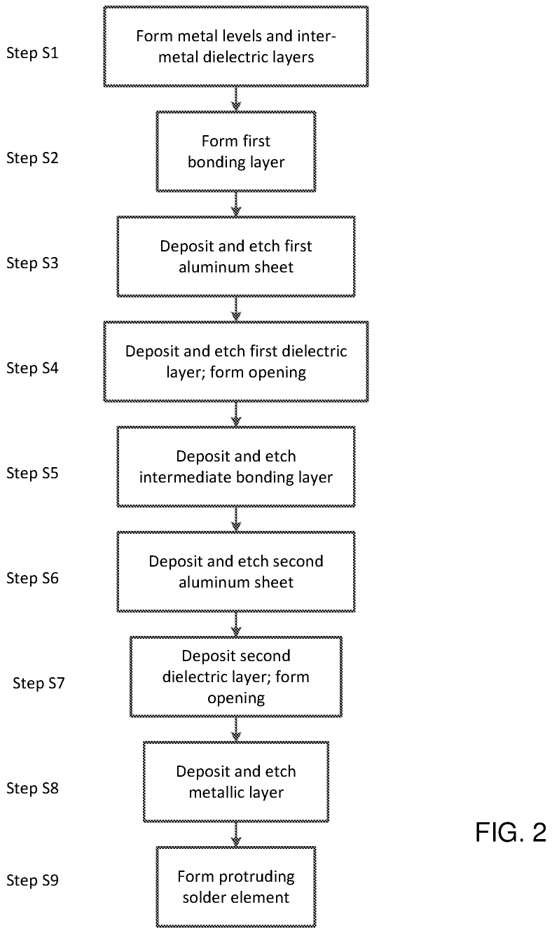

Advantageously, the inter-metal dielectric layers can be produced (step S1, FIG. 2) from a material having a low dielectric constant (i.e., less than the dielectric constant of silicon dioxide, for example between 2 and 3). A connection site is intended to receive the protruding solder element ES. The connection site is located on a top surface of the last metal level Mn of the interconnection part.

The connection site forms a buffer zone between the interconnection part and the protruding solder element ES, the buffer zone is particularly intended to absorb mechanical stress liable to cause delaminations in the inter-metal dielectric layers between the metal levels of the interconnection part.

During the assembly of the integrated circuit, the protruding solder element ES will be soldered to a third-party device. This soldering applies a temperature variation and therefore expansions creating mechanical stress which can cause delaminations between the layers of materials belonging to the interconnection part.

Indeed, the expansion coefficients of the third-party device and the internal circuit can be different, to such an extent that the respective deformations of the third-party device and the integrated circuit induce said stress in the interconnection part.

The connection site comprises a first aluminum sheet A1, and at least a second aluminum sheet A2 disposed on the first aluminum sheet A1. The bottom surface of the first aluminum sheet A1, for example of circular shape, at least partially covers the last metal level Mn.

The second aluminum sheet A2 is formed on the first aluminum sheet A1.

Adding the second aluminum sheet A2 onto the first aluminum sheet A1 makes it possible particularly to increase the thickness of the connection site. Indeed, typically the first and the second aluminum sheets A1, A2, are conformal layers, and conformal layers are conventionally limited in thickness by the production method thereof, for example a vapor phase deposition for example of the “PVD” (acronym of the standard term “Physical Vapor Deposition”) type.

Thus, the connection site includes a double thickness of aluminum sheets A1, A2, which absorbs the mechanical stress inducing delaminations. The double thickness of aluminum sheets A1, A2 has a buffer, or damping, effect on the stress.

The protruding solder element ES is disposed on the connection site, above a top surface of the second aluminum sheet A2. The protruding solder elements ES can include, advantageously, a copper pillar, and a protruding cap produced from a tin and silver alloy. The protruding cap then forms an interface with the outside of the integrated circuit, this interface is intended to be typically soldered to a third-party device.

Moreover, a first dielectric layer OX, typically composed of silicon oxide covers and electrically insulates a part of the last metal level Mn of the interconnection part.

The first dielectric layer OX has an opening leading to (i.e., exposing a portion of the upper surface of) the first aluminum sheet A1. Nevertheless, the first dielectric layer OX partially covers the edges of the first aluminum sheet A1.

The second aluminum sheet A2 has a profile which adapts to the relief created by the opening of the dielectric layer OX. The second aluminum layer A2 is conformal and therefore also rests partially on the edges of the opening of the first dielectric layer OX, as well as on the first aluminum sheet A1 at the level of the opening of the first dielectric layer OX.

Advantageously, and as illustrated in the enlargement of the central zone of FIG. 1, a first bonding layer CA1, an intermediate bonding layer CI, and a metallic layer MS under the protruding solder element, can be disposed in the connection site.

The first bonding layer CA1 is located between the first aluminum sheet A1 and the last metal level Mn made of copper.

The intermediate bonding layer CI is located between the first aluminum sheet A1 and the second aluminum sheet A2.

The metallic layer MS, for example made of a titanium tungsten copper alloy, is located under the protruding solder element ES and on the second aluminum sheet A2.

The first bonding layer CA1, and the intermediate bonding layer CI are each composed of at least one layer of tantalum and/or at least one layer of tantalum nitride.

Optionally, the first bonding layer CA1, and the intermediate bonding layer CI, can comprise a stack of layers of tantalum and tantalum nitride.

The link between copper and aluminum is, for example, promoted by the first bonding layer CA1 located between the first aluminum sheet A1 and the last metal level Mn made of copper, or indeed by the metallic layer MS located under the protruding solder element ES and on the second aluminum sheet A2.

A second dielectric layer PA, usually referred to as passivation layer, for example composed of silicon oxide and silicon nitride, covers the first dielectric layer OX. The dielectric layer PA has an opening leading to (i.e., exposing a portion of the upper surface of) the second aluminum sheet A2. The dielectric layer PA partially covers the edges of the second aluminum sheet A2.

Finally, an organic resin layer PI, for example composed of polyimide, covers the second dielectric layer PA. The organic resin layer PI has an opening leading to the second aluminum sheet A2. The opening of the organic resin layer PI and the opening of the second dielectric layer PA are centered on the same axis and thus leave an opening on the connection site to receive the protruding solder element ES.

The protruding solder element ES rests on the connection site and also on flanks and on the edges of the opening of the organic resin layer PI.

The connection site described thus far can be obtained particularly by means of the following production techniques (step S1), wherein metal levels M1, Mn and inter-metal dielectric layers DIMn, DIMn−1, DIM1 separating the metal levels have been formed. Optionally, the inter-metal dielectric layers DIMn, DIMn−1, DIM1 have been formed in a material having a low, or even ultra-low, dielectric constant.

The first bonding layer CA1 can be formed on the top surface of the last metal level Mn, by means of a vapor phase deposition, for example of the “CVD” (acronym of the standard term “Chemical Vapor Deposition”) type (step S2).

During a step S3, the first aluminum sheet A1 can then be formed on the first bonding layer CA1 by means of a solid-sheet vapor phase deposition, for example of the “PVD” type, followed by a dry etching (step S3) using a mask, the pattern of which protects the first aluminum sheet A1 at the location of the future connection site. The dry etching (step S3) can also etch the first bonding layer CA1. Alternatively, the first aluminum sheet A1 is formed directly on the last metal level Mn, by the same deposition and etching steps S3.

During a step S4, the first dielectric layer OX can then be formed on the top surface of the last metal level Mn and of the first aluminum sheet A1, by means of a vapor phase deposition, for example of the “CVD” type, followed by a “CMP” (acronym of the standard term “Chemical-Mechanical Polishing”) type chemical-mechanical polishing.

The opening of the first dielectric layer OX, leading to the first aluminum sheet A1, can be consequently produced (step S4) in another dry etching step using a mask, the pattern whereof exposes the first dielectric layer OX at the location of the future connection site.

The intermediate bonding layer CI can be formed (step S5) on the first aluminum sheet A1, in the opening of the first dielectric layer OX, by means of a vapor phase deposition, for example of the “CVD” type, followed by a dry etching.

Similarly to the formation of the first aluminum sheet A1, the second aluminum sheet A2 can be formed (step S6) on the intermediate bonding layer CI, in the opening of the first dielectric layer OX, by means of a solid-sheet vapor phase deposition, for example of the “PVD” type, followed by a dry etching. Alternatively, the second aluminum sheet A2 can be formed (step S6) directly on the first aluminum sheet A1, in the opening of the first dielectric layer OX.

The second dielectric layer PA can be formed (step S7) on the second dielectric layer OX, by means of a chemical vapor phase deposition, for example of the “CVD” type, following by a chemical-mechanical polishing for example of the “CMP” type. The opening of the second dielectric layer PA, leading to the second aluminum sheet A2, can then be produced by means of another dry etching step (step S7).

The metallic layer MS can be formed (step S8) on the second aluminum sheet A2, and on the edges of the opening of the organic resin layer PI, by means of a vapor phase deposition, for example a cathode sputtering, followed by a dry etching.

The protruding solder element ES can be finally formed (step S9) on the metallic layer MS, for example in the form of a pillar, during a step comprising an electrolytic growth or a galvanization of a metal, such as copper. Alternatively, the protruding solder element ES can be formed directly on the second aluminum sheet A2 in the opening of the first dielectric layer OX and in the opening of the second dielectric layer PA.

1. An integrated circuit, comprising:
an interconnection part including a last metal level and at least one protruding solder element disposed on a connection site;
wherein the connection site includes:
a first aluminum sheet in electrical connection with the last metal level;
a second aluminum sheet disposed between the first aluminum sheet and the protruding solder element; and
an intermediate bonding layer located between the first aluminum sheet and the second aluminum sheet;
wherein said intermediate bonding layer is made of a material selected from the group consisting of tantalum and tantalum nitride.

2. The integrated circuit according to claim 1, wherein said intermediate bonding layer is made of a stack of layers.

3. The integrated circuit according to claim 2, wherein said stack comprises at least one layer of tantalum and at least one layer of tantalum nitride.

4. The integrated circuit according to claim 1, further comprising a further intermediate bonding layer located between the first aluminum sheet and the last metal level of the interconnection part.

5. The integrated circuit according to claim 4, wherein said further intermediate bonding layer is made of a material selected from the group consisting of tantalum and tantalum nitride.

6. The integrated circuit according to claim 1, wherein the protruding solder element is a copper pillar.

7. The integrated circuit according to claim 1, wherein the interconnection part further includes at least one inter-metal dielectric layer, said at least one inter-metal dielectric layer including a material having a low dielectric constant.

8. The integrated circuit according to claim 1, further comprising a dielectric layer partially coating said first aluminum sheet, wherein said dielectric layer comprises an opening facing the first aluminum sheet, and wherein the second aluminum sheet extends into the opening and further rests on sidewalls of the opening and rests on parts of the dielectric layer covering the first aluminum sheet.

9. A method for producing an integrated circuit, comprising:
forming an interconnection part including a last metal level;
forming a connection site comprising:
forming a first aluminum sheet in electrical connection with the last metal level of the interconnection part;
forming an intermediate bonding layer;
forming a second aluminum sheet;
wherein intermediate bonding layer located between the first aluminum sheet and the second aluminum sheet; and
wherein said intermediate bonding layer is made of a material selected from the group consisting of tantalum and tantalum nitride; and
forming at least one protruding solder element on the connection site and above the second aluminum sheet.

10. The method according to claim 9, wherein forming the intermediate bonding layer comprises forming a stack of layers.

11. The method according to claim 10, wherein the stack includes at least one layer of tantalum and at least one layer of tantalum nitride.

12. The method according to claim 19, further comprising forming a further intermediate bonding layer located between the first aluminum sheet and the last metal level of the interconnection part.

13. The integrated circuit according to claim 12, wherein said further intermediate bonding layer is made of a material selected from the group consisting of tantalum and tantalum nitride.

14. The method according to claim 9, wherein the protruding solder element comprises a copper pillar.

15. The method according to claim 9, wherein forming the interconnection part comprises forming at least one inter-metal dielectric layer, said at least one inter-metal dielectric layer including a material having a low dielectric constant.

16. The method according to claim 9, wherein forming the connection site further comprises:
forming a dielectric layer so as to cover the first aluminum sheet; and
forming an opening in the dielectric layer facing the first aluminum sheet; and
forming the second aluminum sheet to extend into the opening and further rest on sidewalls of the opening and rest on parts of the dielectric layer covering the first aluminum sheet.

17. The method according to claim 9, wherein forming the first aluminum sheet and forming the second aluminum sheet each comprise performing a vapor phase deposition of aluminum and etching the deposited aluminum.

18. The method according to claim 9, wherein forming the intermediate bonding layer comprising performing a vapor phase deposition of said material and etching the deposited material.
